(19) United States
(12) Patent Application Publication
(10) Pub. No.: US 2009/0263581 A1
(43) Pub. Date: Oct. 22, 2009

(54) METHOD AND APPARATUS TO COAT OBJECTS WITH PARYLENE AND BORON NITRIDE

(75) Inventors: Sidney Edward Martin, III, Fairhaven, MA (US); Eric Roger Dawicki, Fairhaven, MA (US); Angela Michele Dawicki, Fairhaven, MA (US)

Correspondence Address: WOLF GREENFIELD & SACKS, P.C., 600 ATLANTIC AVENUE, BOSTON, MA, 02210-2206, US

(73) Assignee: Northeast Maritime Institute, Inc., Fairhaven, MA (US)

(21) Appl. No.: 12/104,080

(22) Filed: Apr. 16, 2008

(51) Int. Cl. C23C 16/22; B32B 27/32; C23C 16/44; C08K 3/38

(52) U.S. Cl. 427/255.395; 524/404; 118/719; 428/335; 428/500; 428/422

(57) ABSTRACT

The present inventions relates to an improved and novel Parylene compositions with has improved heat transfer and durability qualities, as well as a methods and apparatus to coat objects with the novel Parylene compositions, and objects coated with the novel Parylene compositions. The novel Parylene composition of the invention comprises Parylene and boron nitride. The invention also includes objects coated with at least one polymer coat and a boron nitride coat.

This application claims priority to Provisional Patent Application No. ______, filed Sep. 5, 2007 (formerly U.S. patent application Ser. No. 11/850,134), Provisional Patent Application No. ______, filed Oct. 23, 2007 (formerly U.S. patent application Ser. No. 11/876,977) and Provisional Patent Application No. ______, filed Oct. 23, 2007 (formerly U.S. patent application Ser. No. 11/876,998), the contents of each prior application incorporated herein by reference.

### BACKGROUND

Parylene conformation coatings are ultra-thin, pinhole-free polymer coatings that are commonly used to protect medical devices, electronics, and products from the automotive, military and aerospace industries. Chemical vapor deposition at low pressure produces the thin, even conformational polymer coating. The resulting Parylene coating has a very high electrical resistively and resists moisture penetration.

Parylene is the generic name for members of a unique polymer series. The basic member of the series, called Parylene N, is poly-para-xylylene, a polymer manufactured from di-p-xylylene ([2,2]paracyclophane). Parylene N is a completely linear, highly crystalline material. Parylene C, the second commercially available member of the series, is produced from the same monomer modified only by the substitution of a chlorine atom for one of the aromatic hydrogens. Parylene D, the third member of the series, is produced from the same monomer modified by the substitution of the chlorine atom for two of the aromatic hydrogens. Parylene D is similar in properties to Parylene C with the added ability to withstand higher use temperatures.

Parylene polymers are deposited from the vapor phase by a process that resembles vacuum metallizing, however, the Parylenes are formed at around 0.1 Torr. The first step is the vaporization of the solid Parylene dimer at approximately 150 degrees C. The second step is the quantitative cleavage (pyrolysis) of the dimer at the two methylene-methylene bonds at about 680 degrees C. to yield the stable monomer diradical, para-xylylene. Finally, monomer enters the room temperature deposition chamber where it simultaneously absorbs and polymerizes on the object to be coated. Adhesion of the Parylene to a wide variety of substances can be improved by pre-treating the object with an organic silane prior to Parylene coating. Two silanes, vinyl trichlorosilane in either xylene, isopropanyl alcohol, or Freon®, and gamma-methacryl-oxypropyltrimethoxy Silane (Silquest® A-174) in a methanol-water solvent have been used.

The Parylene deposition process is generally carried out in a closed system under negative pressure. The closed system generally has separate chambers for the vaporization, pyrolysis and deposition of the Parylene, with the chambers being connected with the appropriate plumbing or tubular connections. Apparatus for chemical vapor deposition of Parylene onto objects are known in the art. See for example, U.S. Pat. Nos. 4,945,856, 5,078,091, 5,268,033, 5,488,833, 5,534,068, 5,536,319, 5,536,321, 5,536,322, 5,538,758, 5,556,473, 5,641,358, 5,709,753, 6,406,544, 6,737,224, and 6,406,544, all of which are incorporated by reference herein.

What is needed are improved Parylene compositions with different characteristics that will expand the application of Parylene coatings. Coatings with greater durability and greater heat transfer properties are particularly sought.

### BRIEF SUMMARY OF THE INVENTION

The first embodiment of the invention provides novel Parylene compositions which may contain Parylene and boron nitride. In these compositions, the Parylene and boron nitride may be inter-dispersed. While any Parylene may be used in these compositions, Parylene D, Parylene C, Parylene N and Parylene HT® may be preferred, and Parylene C may be particularly preferred. In these compositions, the boron nitride may have a hexagonal plate structure. In some embodiments, the weight of boron nitride to the total weight of Parylene and boron nitride may be less then about 80%.

The novel Parylene compositions of the invention may have greater thermal conductivity than the Parylene alone, and in particular greater than about 10% thermal conductivity than the Parylene alone. Alternatively or additionally, the Parylene compositions may have a greater hardness than the Parylene alone, and particularly greater than about 10% hardness than the Parylene alone.

A second embodiment of the invention provides a method to apply a coating of Parylene and boron nitride to an object, which may have the steps of: (A.) vaporizing Parylene dimers by heating them to about 150 to about 200 degrees C. to form gaseous Parylene dimers; (B.) cleaving gaseous Parylene dimers to gaseous Parylene monomers by heating gaseous Parylene dimers to about 650 to about 700 degrees C.; (C.) injecting boron nitride into the gaseous Parylene monomers of Step B; and (D.) contacting the object to be coated with Parylene with the gaseous Parylene monomers and boron nitride of Step C for sufficient time to deposit coat of Parylene and boron nitride of a final thickness. While any Parylene may be used in this method, Parylene D, Parylene C, Parylene N and Parylene HT® may be preferred, and Parylene C may be particularly preferred. In some preferred embodiments, the boron nitride may be injected into the gaseous Parylene monomers as a powder, preferably between about 18 micron and about 25 micron. In other embodiments, Step D may take place at about 5 degrees to about 30 degrees C. In some embodiments, the final thickness of the coat may be between about 100 Angstrom to about 3.0 millimeters. In some embodiments, the method may have an additional Step E in which the object to be coated may be contacted with a silane composition until the object is coated with silane.

The method provided in the invention may be used to coat objects such as electronics equipment, circuit boards, paper, textiles, ceramics, plastics, frozen liquids, batteries, speakers, solid fuel, medical devices, and space suits. In some embodiments, the object to be coated may be one that generates or consumes heat and/or requires a rugged coating. Further embodiments may include the objects coated by the method to apply a coating of Parylene and boron nitride to an object.

A third embodiment of the invention provides an apparatus to apply a coating of a polymer and a powder, which may include a vaporization chamber; operably linked to a pyrolysis chamber; a vacuum chamber and a connection comprising a T-port operably linking the pyrolysis chamber to the vacuum chamber. In some embodiments, the connection operably linking the pyrolysis chamber and the vacuum chamber may be a means for transmitting gas from the pyrolysis chamber to the vacuum chamber. In other embodiments, the T-port may be operably connected to a means for injecting a powder into the gas transmitted through the connection. In some embodiments, the vacuum chamber may contain a deposition chamber operably linked to the pyrolysis chamber and a vacuum means, where the vacuum means may be one or more vacuum pumps.

A fourth embodiment of the invention provides objects which may be coated with Parylene and boron nitride. In some embodiments, the boron nitride may be inter-dispersed the Parylene in the coating. In some embodiments, the object may be one that benefits from thermal conductivity through the Parylene coating, such as where the object is generates heat or absorbs heat, including electronics equipment, heat packs, refrigeration devices, heaters, and drilling equipment. In some embodiments, the object may be expected to be subjected to harsh physical impact during its lifetime. While any Parylene may be used in these objects, Parylene C, Parylene N, Parylene D and Parylene HT® may be preferred, and Parylene C particularly preferred. In some embodiments, the coating may be about 0.0025 mm to about 0.050 mm thick.

A fifth embodiment of the invention provides a polymer-coated object, which may be an object coated with at least one coat of a polymer and at least one coat of boron nitride. In some embodiments, the polymer may be polynaphtahlene, diamine, polytetrafluoroethylene, polyimides, silicas, titania, aluminum nitride, and lanthanum hexaboride, Parylene C, Parylene N, Parylene D or Parylene HT®, and may be preferably Parylene C. In some embodiments, the boron nitride coat may be closer to the object that the polymer coat, while in other embodiments, the polymer coat may be closer to the object that the boron nitride coat. In some embodiments, the coatings of boron nitride and polymer may be at least about 0.05 mm thick each. In some embodiments, the object may generate heat or absorb heat, such as cold packs, frozen liquids and gases and heat pumps. In some embodiments, the object may be expected to be subjected to harsh physical impact during its lifetime.

### BRIEF DESCRIPTION OF DRAWINGS

Further advantages of the present invention may be understood by referring to the following descriptions taken in conjunction with the accompanying drawings, in which:

FIG. 1 is are diagrams of the chemical structures of varieties of Parylene and Silquest®. FIG. 1A is a diagram of Parylene N. FIG. 1B is a diagram of Parylene C. FIG. 1C is a diagram of Parylene D. FIG. 1D is a diagram of Parylene HT®. FIG. 1E is a diagram of Silquest® A-174 (also known as Silquest® A-174(NT))

FIG. 2 is a schematic diagram of one embodiment of the apparatus of the invention to apply a coating of Parylene and powder.

FIG. 3 is a schematic diagram of three embodiments of the Parylene-coated objects of the invention. FIG. 3A depicts an object coated with separate layers of Parylene and boron nitride, where the boron nitride layer is closest to object. FIG. 3B depicts an object coated with separate layers of Parylene and boron nitride, where the Parylene layer is closest to object. FIG. 3C depicts an object coated with a layer of Parylene inter-dispersed with boron nitride.

### DETAILED DESCRIPTION

It is to be understood that the figures and descriptions of the present invention have been simplified to illustrate elements that are relevant for a clear understanding of the present invention, while eliminating, for purposes of clarity, other elements of a conventional Parylene coating method or apparatus. For example, certain Parylene coating systems may include multiple deposition chambers that are not described herein. Those of ordinary skill in the art will recognize, however, that these and other elements may be desirable in a typical Parylene coating system. However, because such elements are well known in the art and because they do not facilitate a better understanding of the present invention, a discussion of such elements is not provided herein.

Also, in the claims appended hereto, any element expressed as a means for performing a specified function is to encompass any way of performing that function including, for example, a combination of elements that perform that function. Furthermore the invention, as defined by such means-plus-function claims, resides in the fact that the functionalities provided by the various recited means are combined and brought together in a manner as defined by the appended claims. Therefore, any means that can provide such functionalities may be considered equivalents to the means shown herein.

For the purposes of this specification, unless otherwise indicated, all numbers expressing quantities of ingredients, time, temperature, thickness of coats, and other properties or parameters used in the specification are to be understood as being modified in all instances by the term “about.” Accordingly, unless otherwise indicated, it should be understood that the numerical parameters set forth in the following specification and attached claims are approximations. At the very least, and not as an attempt to limit the application of the doctrine of equivalents to the scope of the claims, numerical parameters should be read in light of the number of reported significant digits and the application of ordinary rounding techniques.

Additionally, while the numerical ranges and parameters setting forth the broad scope of the invention are approximations as discussed above, the numerical values set forth in the Example section are reported as precisely as possible. It should be understood, however, that such numerical values inherently contains certain errors resulting from the measurement equipment and/or measurement technique.

Any patent, publication, or other disclosure material, in whole or in part, that is said to be incorporated by reference herein is incorporated herein only to the extent that the incorporated material does not conflict with the existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements or other disclosure material set forth herein will only be incorporated to the extent that no conflict arises between the incorporated material and the existing disclosure material.

The present invention relates to improved and novel Parylene compositions with has improved heat transfer and durability qualities, as well as methods and apparatus to coat objects with the novel Parylene compositions, and objects coated with the novel Parylene compositions. The present invention further relates to objects with coats of at least one polymer and boron nitride.

The novel Parylene compositions of the invention contain Parylene and boron nitride. Standard Parylene coating is insulating, and does not readily allow the coated object to release heat into the environment. This characteristic of Parylene is problematic for objects such as electronics equipment that generate heat, which, if not dissipated, can lead to early failure of the equipment. The novel Parylene coating of the invention allows heat to dissipate from the coated object as compared to the Parylene alone coating, and is therefore useful to coat objects that require heat dissipation, either by releasing heat or absorbing heat. The novel Parylene coating composition of the invention also has increased hardness compared to a coating of Parylene alone. Therefore, the novel Parylene coating composition is also useful to coat objects that require a more rugged protective coat, such as those that will be subjected to harsh physical impact during their lifetime.

The method of the invention to coat objects with the novel Parylene-boron nitride compositions may be used on products used in the commercial marine, recreational boating, military (aerospace and defense), industrial and medical industries, as well as others. The coating process is specifically designed to “seal” the devices, which protects those types of devices commonly used in marine and hazardous environments against operational malfunction caused by exposure to moisture, immersion in water, dust, effects of high wind and chemicals. The coating will enhance the survivability and sustainability of operational equipment and high value specialty products susceptible to corrosion and degradation.

The method applies a uniform, thin layer of Parylene-boron nitride coating within a vacuum chamber at 25 degrees C. using standard chemical vapor deposition practices in thicknesses ranging from 0.01 to 3.0 millimeters, depending on the item coated. The item once coated is weatherproof and water resistant, and can withstand exposure to extreme weather conditions and exposure to most chemicals. Any solid surface can be coated, including plastics, metals, woods, paper and textiles. Sample applications include, but are not limited to: electronics equipment, such as cell phones, radios, circuit boards and speakers; equipment used in ocean and space exploration; hazardous waste transportation equipment; medical instruments; paper products; and textiles.

One embodiment of the invention is a novel Parylene composition that contains, among other things, Parylene and boron nitride. In some embodiments, the composition may consist essentially of Parylene and boron nitride. In other embodiments, the composition consists of Parylene and boron nitride. In some embodiments, the Parylene and boron nitride comprise at least about 50%, at least about 70%, at least about 90%, or at least about 95% of the composition.

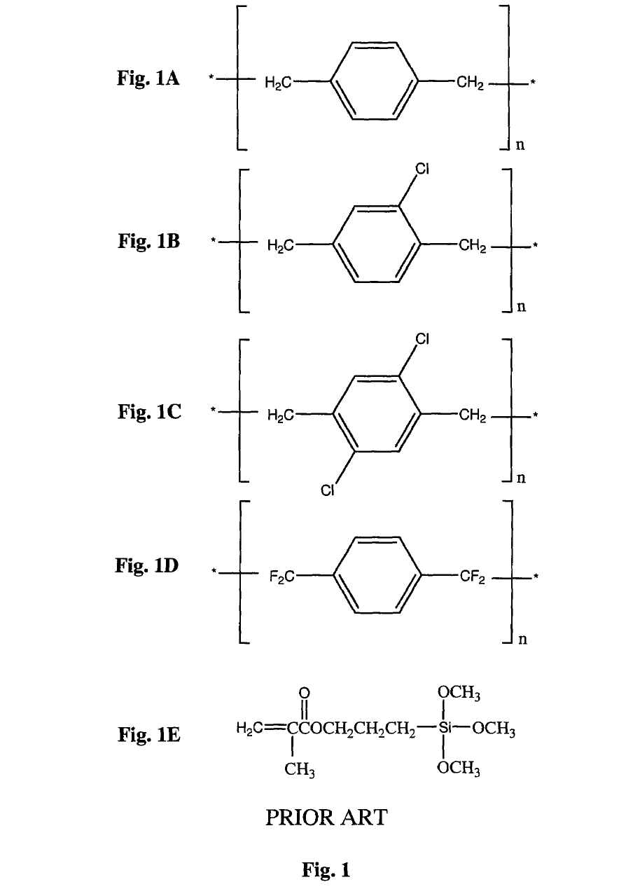

While in preferred embodiments, this Parylene-boron nitride composition may contain Parylene C, in other embodiments, it may contain Parylene D, Parylene N or Parylene HT®. FIGS. 1A, 1B, 1C and 1D. In some embodiments, the Parylene may be derived from Parylene N, or poly-para-xylylene, by the substitution of various chemical moieties. In preferred embodiments, the Parylene forms a completely linear, highly crystalline material. In some embodiments, the boron nitride may have a hexagonal plate structure. In some embodiments, the Parylene and boron nitride form separate layers within the Parylene composition. In some embodiments, the Parylene composition may have strong covalent bonds within the Parylene and boron nitride layers. In other embodiments, the Parylene composition may have weak Van der Waals forces between the Parylene and boron nitride layers.

In some embodiments, the Parylene composition of the invention may have greater thermal conductivity than Parylene alone as measured in (cal/sec)/cm²/C. In specific embodiments, the Parylene-boron nitride composition may have greater than about 10%, greater than about 30%, or greater than about 50% thermal conductivity than the Parylene alone. In other embodiments, the Parylene composition of the invention may have greater hardness than Parylene alone as defined by Rockwell hardness test. E. L. Tobolski & A. Fee, Macroindentation Hardness Testing, ASM Handbook, Volume 8: Mechanical Testing and Evaluation, 203-211 (ASM International, 2000). In specific embodiments, the Parylene-boron nitride composition may have greater than about 10%, greater than about 30%, greater than about 50% or greater than about 90% hardness than the Parylene alone. The relative amounts of Parylene and boron nitride in the Parylene-boron nitride composition may determine the thermal conductivity and hardness of the composition. In some embodiments, the weight of boron nitride in the total weight of Parylene and boron nitride in the composition will be less than about 5%, less than about 10%, less than about 20%, less than about 40%, less than about 60%, or less than about 80%.

The method of the invention to coat objects with a composition of Parylene and boron nitrite may include the following several steps:
A. vaporizing Parylene dimer form by heating to 150-200 degrees C. to form gaseous Parylene dimers;
B. cleaving gaseous Parylene dimers to gaseous Parylene monomers by heating gaseous Parylene dimers to 650 to 700 degrees C.;
C. injecting boron nitride into the gaseous Parylene monomers of Step B; and
D. contacting object to be coated with gaseous Parylene monomers and boron nitride for sufficient time to deposit coat of Parylene of a final thickness.

Steps A and B of the method to coat objects with Parylene may be performed by any manner that is currently in use for the vapor coating of objects with Parylene, as will be well known to those of ordinary skill in the art. Further, the steps of the invention may be performed in an order different than the one presented. In preferred embodiments, Parylene C is used. In other embodiments, other forms of Parylene may be used, including but not limited to, Parylene N, Parylene D and Parylene HT®. In some embodiments, the Parylene may be derived from Parylene N, or poly-para-xylylene, by the substitution of various chemical moieties. In preferred embodiments, the Parylene forms a completely linear, highly crystalline material. In the Example, one embodiment of the method is set forth with a more detailed description on how the steps of the method may be performed.

In some embodiments, Step A, vaporizing Parylene dimer form by heating to 150-200 degrees C. to form gaseous Parylene dimers, may be performed in a furnace chamber. In some embodiments, Step B, cleaving gaseous Parylene dimers to gaseous Parylene monomers by heating gaseous Parylene dimers to 650 to 700 degrees C., may be performed in a furnace chamber.

In preferred embodiments, Step C, injecting boron nitride into the gaseous Parylene monomers of Step B, may be performed after Step B. In some embodiments, the boron nitride may be injected into the gaseous Parylene monomer as a powder. One embodiment of this step is described in the Example. In some embodiments, the boron nitride powder may be at least about 500 grit. In preferred embodiments, the boron nitrate powder is between about 18 micron and about 25 micron.

In Step D, the object to be coated may be contacted with gaseous Parylene monomers and boron nitride for sufficient time to deposit a coat of Parylene and boron nitride on the object. In preferred embodiments, this step may be performed in a deposition chamber. In other preferred embodiments, the deposition chamber and the objects to be coated may be at room temperature, from about 5 degrees C. to about 30 degrees C., or most preferably from about 20 degrees C. to about 25 degrees C. In some embodiments, the length of time that the object may be contacted with the gaseous Parylene monomers and boron nitride may be varied to control the final thickness of the Parylene-boron nitride coat on the object. In various embodiments, the final thickness of the Parylene-boron nitride coating may be between about 100 Angstrom to about 3.0 millimeters. In some embodiments, Parylene is deposited from about 8 hours to about 18 hours to obtain a coat thickness of about 0.05 mm. In preferred embodiments, the final thickness of the Parylene coating may be between about 0.5 millimeters to about 3.0 millimeters. The choice of final thickness of Parylene coating depends to some degree on the object to be coated and the final use of the object. Thinner final coats may be desirable for objects that require some movement to be functional, such as power buttons. Thicker coatings may be desirable for objects that will be submerged in water.

In some embodiments, the method may have the additional step E of contacting the object to be coated with a silane composition until the object is coated with silane. In preferred embodiments, this step may be performed prior to Step D. In some embodiments, the silane composition may be in solution when the object is contacted with it. In other embodiments, the silane composition may be in a gas when the object is contacted with it. In some embodiments, the silane composition may be Silquest® A-174 (FIG. 1E) This step is particularly advantageous to aid the Parylene coating hydrophilic surfaces of objects.

Another embodiment of the invention are the objects coated with Parylene and boron nitride composition by the method of the invention. The objects to be coated by this method may be any object that has a solid surface at the temperature at which the object is contacted with the gaseous Parylene monomers and boron nitride. Such objects include, but are not limited to, electronics equipment, circuit boards, paper, textiles, ceramics, plastics, frozen liquids, batteries, speakers, solid fuel, medical devices, paper, and hazardous waste transportation equipment, hazardous waste, medical instruments, equipment used in ocean and space exploration, space suits. In some embodiments, the object may be one which generates heat or consumes heat, such as, but not limited to, computers, drill equipment for deep hole drilling, exposed electronics on oil rigs. In other embodiments, the object may be one that requires a particularly rugged coating.

The coating compositions, methods and coated objects may be particularly suited for the use in the harsh environmental conditions encountered by the military. In some embodiments, the object coated with may meet the applicable requirements of military specifications MIL-PRF-38534, the general performance requirements for hybrid microcircuits, Multi-Chip Modules (MCM) and similar devices. In some embodiments, the Parylene-coated object may meet the applicable requirement of military specifications MIL-PRF-38535, the general performance requirements for integrated circuits or microcircuits. In some embodiments, the Parylene-coated object may meet the applicable requirements of both military specifications MIL-PRF-38534 and MIL-PRF-38535.

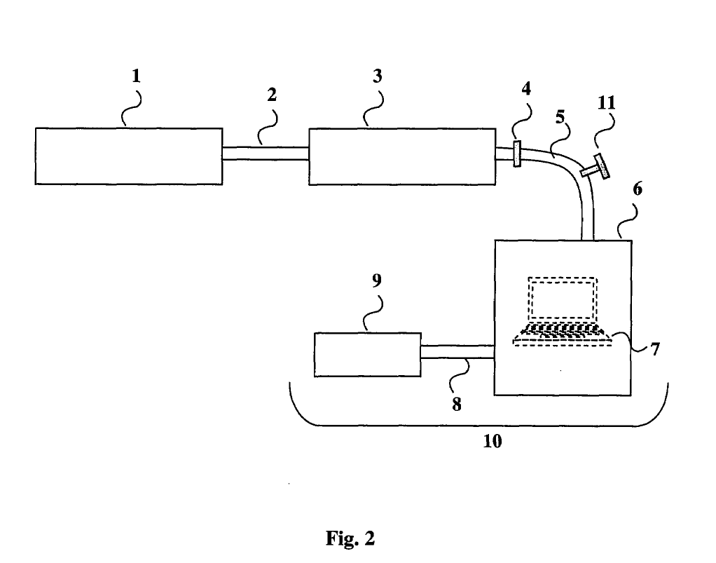

Another embodiment of the invention is an apparatus useful for the chemical vapor deposition of the Parylene and boron nitride composition which contains a means to inject a powder into the chemical vapor prior to deposition. FIG. 2 shows a coating apparatus according to one embodiment of the present invention. The vaporization chamber 1 may be operably linked to the pyrolysis chamber 3 by a component 2 that may be capable of communicating gas from the vaporization chamber 1 to the pyrolysis chamber 3. The pyrolysis chamber 3 may be operably linked to the vacuum chamber 10, which may comprise a deposition chamber 6 and may be operably linked to a vacuum means 9 by a component 8 which may be capable of pulling a vacuum on the deposition chamber 6. The component 5 operably linking the pyrolysis chamber 3 to the vacuum chamber 10 may be capable of communicating gas from the pyrolysis chamber 3 to the vacuum chamber 10, and also may include a valve 4 that is capable of regulating the flow of gas from the pyrolysis chamber 3 to the vacuum system 10. Component 5 may also have a T-port 11, also called a “tee nipple.” In some embodiments, the T-port may be operably connected to a means for injecting a powder into the gas transmitted through component 5. In some embodiments, the means for injecting a power includes, but is not limited to, ovens, power coat equipment and compressed air. In a preferred embodiment, the means for injecting a power includes a power container operably linked to an electronic valve, which is operably linked to the T-port.

The vaporization chamber 1 may be any furnace/heating system that is capable of heating a solid to about 150 to about 200 degrees C. In some embodiments, the vaporization chamber 1 may be capable of containing gases. Finally, the vaporization chamber 1 may be capable of maintaining a high vacuum.

The vaporization chamber 1 may be operably linked to the pyrolysis chamber 3 by many components that will be well known to those of ordinary skill in the art. The operable connection between the vaporization chamber 1 and pyrolysis chamber 3 may be, in some embodiments, a connection that allows gas to pass from the vaporization chamber 1 to the pyrolysis chamber. In some embodiments, this component 2 may be a glass tube, a retort, or a metal tube, among others. In other embodiments, this component 2 may also contain valves, temperature sensors, other sensors, and other conventional components, as will be well know to those in the art.

The pyrolysis chamber 3 may be any furnace/heating system that is capable of heating a gas to about 650 to about 700 degrees C. In some embodiments, the pyrolysis chamber 3 may be capable of containing gases. Finally, in some embodiments, the pyrolysis chamber 3 may be capable of maintaining a high vacuum, preferably at least 0.1 Torr.

The pyrolysis chamber 3 may be operably linked to the vacuum system 10 by many components that will be well known to those of ordinary skill in the art. The operable connection between the pyrolysis chamber 3 and the vacuum system 10 may be, in some embodiments, a connection that allows gas to pass from the pyrolysis chamber 3 to the vacuum system 10. In some embodiments, this component 5 may be a glass tube, a retort, or a metal tube, among others. In other embodiments, this component 5 may contain valves, temperature sensors, other sensors, and other conventional components, as will be well know to those in the art. In a preferred embodiment, component 5 may contain one or more valves 4 by which the flow of gas through the component 5 may be regulated.

The vacuum system 10 may contain a deposition chamber 6 which may be operably connected 8 to a vacuum means 9. In some embodiments, the connector 8 may be capable of holding a vacuum up to at least about 0.05 Torr. In other embodiments, the vacuum means 9 may be one or more vacuum pumps, which may be capable of pulling a vacuum on the deposition chamber of at least about 0.05 Torr. In some embodiments, the deposition chamber 6 may be of sufficient size to contain the object to be coated 7. In other embodiments, the deposition chamber 6 may be capable of holding an vacuum of at least about 0.05 Torr.

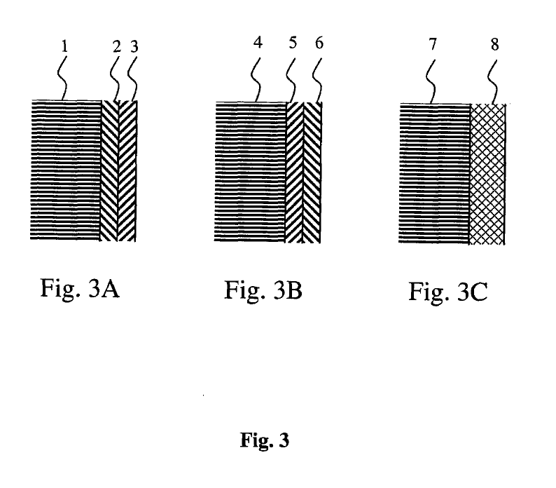

Another embodiment of the invention is an object coated with Parylene and boron nitride. In some embodiments, the Parylene and the boron nitride may be inter-dispersed within the coating 8 on the object 7. FIG. 3C. In some embodiments, the inter-dispersion of the Parylene and the boron nitride may be on the molecular level. In some embodiments, the coating of inter-dispersed Parylene and boron nitride may about 0.0025 mm to about 0.050 mm. In other embodiments, the inter-dispersed Parylene and boron nitride coat may be less that about 2.0 mm.

In other embodiments, at least one polymer coating, such as Parylene, and the boron nitride are found in separate layers on the object. Polymer coatings of interest include, but are not limited to, polynaphtahlene (1-4-napthalene), diamine (O-tolidine), polytetrafluoroethylene (Teflon®), polyimides, silicas (SiO₂), titania (TiO2), aluminum nitride (AlN), and lanthanum hexaboride (LaB₆). In preferred embodiments, the polymer coating may be Parylene C. In other embodiments, other forms of Parylene may be used, including but not limited to, Parylene N, Parylene D and Parylene HT®. In preferred embodiments, the layers of boron nitride and polymer coating may be about 0.05 mm thick each. In other preferred embodiments, each layer may contain essentially the polymer coating or essentially boron nitride. In some embodiments, the boron nitrate layer 2 may be closer to the object 1 than the Parylene layer 3. FIG. 3A. In other embodiments, the Parylene layer 5 may be closer to the object 4 than the boron nitride 6. FIG. 3B.

The object may be any object that has a solid surface at the temperature at which the object is contacted with the gaseous polymer coating and boron nitride. Such objects include, but are not limited to, electronics equipment, circuit boards, paper, textiles, ceramics, plastics, frozen liquids, batteries, speakers, solid fuel, medical devices, paper, and hazardous waste transportation equipment, hazardous waste, medical instruments, equipment used in ocean and space exploration and space suits. In preferred embodiments, the object may one which benefits from a higher thermal conductivity through the polymer coating. In some embodiments, the object may be one which generates heat or absorbs heat. In other embodiments, the object may be one that requires a particularly rugged coating. In some embodiments, the object may be, but is not limited to, an electronics equipment, heat packs, cold packs, refrigerators, heat pumps, frozen liquids and solids.

### EXAMPLE

This example describes one embodiment of the method and apparatus used to coat an object with Parylene and boron nitride. This embodiment uses Parylene C.

### Coating Process

The apparatus will consist of two sections: (1) a furnace/heating section; and (2) a vacuum section. The furnace section will be made up of two furnaces which are connected by glass tubes referred to as retorts. The furnace and vacuum sections will be connected by valves that allow gas flow between the furnace and vacuum sections.

The furnace portion of the equipment is produced to custom design to meet NMI's specifications and requirements by Mellen Furnace Co. (Concord, N.H.). The vacuum portion is produced to custom design by Laco Technologies Inc. (Salt Lake City, Utah).

The process to coat items with Parylene and boron nitride will be is as follows:

(1) First Furnace Chamber. Parylene C in Dimer form (two molecule form) in an amount sufficient to coat the item will be placed in the furnace chamber. The items will be coated in a thickness ranging from 0.01 to 3.0 mms. The Parylene C will be placed in a stainless steel “boat” (a standard container made out of metal or glass) that is inserted into the furnace through a vacuum secured opening of the tube (the boat is pushed with a rod into the furnace). The opening will be sealed after inserting the Parylene C. The furnace will be then brought to 150-200 degrees C. to create an environment in which the solid Parylene C becomes a gas. The gas will be held in the first furnace chamber until two valves open. The first of two valves will not open until the cold traps in the vacuum section are filled with liquid nitrogen (LN2) and the traps are “cold”. The LN2 will be purchased from a local supply house. The LN2 will be placed into a one gallon container at the supplier. The LN2 will be poured from the container into the “trap.” The second valve will be variable and is opened when the gas is pulled from the first furnace by vacuum.

(2) Second Furnace Chamber. The Parylene C gas will move to the second furnace which is a temperature of 650 to 700 degrees C. The heat in this furnace will cause the Parylene C gas to separate into individual molecules (monomers). The gas in monomer form will be then pulled by vacuum into the deposition chamber.

Boron nitride in powder form will be placed in a KF16 tube that is connected to a KF connection tube that has a “T” KF16 port. This KF16 tube will be partially filled with a “charge” of boron nitride powder (minimum of 500 grit). The KF16 tube will be capped. After the coating process is initiated, the boron will be injected into the coating “stream.” The boron flows as a powder and will become entrapped with the deposition of the coating process.

The KF16 tube will be attached to the retort perpendicular to the flow of the monomer gas just before it enters the deposition chamber. There will be a valve that is opened which allows the boron nitride to flow into the gas. The gas will bind with the monomer and is deposited on the items to be coated. This process will be similar to powder coating. The process may be repeated to increase the amount of boron nitride inserted into the coating on the items. While not limiting the characteristics of the boron nitride/Parylene coating, it is thought that boron nitride improves the hardness of the coat and supplies a method to better allow the heat to escape the coated object, such as an electronic device. The boron nitride will be inserted into the Parylene as a dust.

(3) Vacuum Chamber. The vacuum portion of the machine will consist of a deposition chamber with two vacuum pumps. The first vacuum pump is a “roughing” pump which pulls down the initial vacuum. The initial vacuum will be in the 1×10⁻³ Torr range. The second stage pump then will pull down to the final vacuum in the 1×10⁻⁴ Torr range. The vacuum pumps will be protected by Liquid Nitrogen traps that protect the pumps from the solidification of the monomer gas by condensing the gas on the cold trap surface.

The items to be coated will be set on shelves in the deposition chamber prior to starting the coating process. The devices to be coated will be masked (with workmanlike methods) in those areas on and within the device that are not to be coated. The masking will be done in areas where electrical or mechanical connectivity must remain. The material will be coated onto the item at room temperature (75 degrees Fahrenheit).

Inside the vacuum chamber there will be a crucible of Silquest® A-174 that is poured into a ceramic crucible. The crucible will be inserted into a 2 inch thermocouple onto a hot plate in the vacuum chamber. The amount of Silquest® A-174 poured depends on the amount of items in the chamber, but will be between 10-100 ml. The plate will heat the Silquest® A-174 to an evaporation point such that it coats the entire area inside the chamber, included any objects within the chamber.

The monomer gas will be pulled by the lower vacuum in the vacuum chamber. When the gas will be pulled into the chamber it is deflected so that it sprays within the entire area of the chamber. The items will be coated as the monomer gas cools. The gas will cool from 600 degrees C. to 25 degrees C. and will harden on the device within the chamber. During that cooling process, the monomers deposit on the surface of the item to be coated will create a polymer three dimensional chain that is uniform and pin hole free. The deposition equipment will control the coating rate and ultimate thickness. The required thickness of a Parylene coating will be determined by time exposed to the monomer gas. The thickness can range from hundreds of angstroms to several millimeters.

While several embodiments of the invention have been described, it should be apparent, however, that various modifications, alterations and adaptations to those embodiments may occur to persons skilled in the art with the attainment of some or all of the advantages of the present invention. For example, in some embodiments of the present invention disclosed herein, a single component may be replaced by multiple components, and multiple components may be replaced by a single component, to perform a given function or functions. Except where such substitution would not be operative to practice embodiments of the present invention, such substitution is within the scope of the present invention. The disclosed embodiments are therefore intended to include all such modifications, alterations and adaptations without departing from the scope and spirit of the present invention as defined by the appended claims.

What is claimed is:

1. A Parylene composition, comprising Parylene and boron nitride.

2. The Parylene composition of claim 1, wherein the Parylene and boron nitride are inter-dispersed.

3. The Parylene composition of claim 1, wherein the Parylene is selected from a group consisting of Parylene D, Parylene C, Parylene N and Parylene HT®.

4. The Parylene composition of claim 3, wherein the Parylene is Parylene C.

5. The Parylene composition of claim 1, wherein the boron nitride has a hexagonal plate structure.

6. The Parylene composition of claim 1, which has greater thermal conductivity than the Parylene alone.

7. The Parylene composition of claim 7, which has greater than about 10% thermal conductivity than the Parylene alone.

8. The Parylene composition of claim 1, which has a greater hardness than the Parylene alone.

9. The Parylene composition of claim 9, which has greater than about 10% hardness than the Parylene alone.

10. The Parylene composition of claim 1, wherein the weight of boron nitride to the total weight of Parylene and boron nitride is less then about 80%.

11. A method to apply a coating of Parylene and boron nitride to an object, comprising the steps of:
A. vaporizing Parylene dimers by heating them to about 150 to about 200 degrees C. to form gaseous Parylene dimers;
B. cleaving gaseous Parylene dimers to gaseous Parylene monomers by heating gaseous Parylene dimers to about 650 to about 700 degrees C.;
C. injecting boron nitride into the gaseous Parylene monomers of Step B; and
D. contacting the object to be coated with Parylene with the gaseous Parylene monomers and boron nitride of Step C for sufficient time to deposit coat of Parylene and boron nitride of a final thickness.

12. The method of claim 11, wherein the Parylene is selected from a group consisting of Parylene D, Parylene C, Parylene N and Parylene HT®.

13. The method of claim 12, wherein the Parylene is Parylene C.

14. The method of claim 11, wherein in Step C, the boron nitride is injected into the gaseous Parylene monomers as a powder.

15. The method of claim 14, wherein the boron nitride powder is between about 18 micron and about 25 micron.

16. The method of claim 11, wherein Step D takes place at about 5 degrees to about 30 degrees C.

17. The method of claim 11, wherein the final thickness of the coat is between about 100 Angstrom to about 3.0 millimeters.

18. The method of claim 11, which has an additional Step E wherein the object to be coated is contacted with a silane composition until the object is coated with silane.

19. The method of claim 11, wherein the object to be coated is selected from the group consisting of electronics equipment, circuit boards, paper, textiles, ceramics, plastics, frozen liquids, batteries, speakers, solid fuel, medical devices, and space suits.

20. The method of claim 11, wherein the object to be coated is one that generates or consumes heat.

21. The method of claim 11, wherein the object to be coated is one that requires a rugged coating.

22. Objects coated by the method of claim 11.

23. An apparatus to apply a coating of a polymer and a powder, comprising
a vaporization chamber; operably linked to a pyrolysis chamber;
a vacuum chamber and
a connection comprising a T-port operably linking the pyrolysis chamber to the vacuum chamber.

24. The apparatus of claim 23, wherein the connection operably linking the pyrolysis chamber and the vacuum chamber is a means for transmitting gas from the pyrolysis chamber to the vacuum chamber.

25. The apparatus of claim 23, wherein the T-port is operably connected to a means for injecting a powder into the gas transmitted through the connection.

26. The apparatus of claim 23, where the vacuum chamber is comprised of a deposition chamber operably linked to the pyrolysis chamber and a vacuum means.

27. The apparatus of claim 26, wherein the vacuum means is one or more vacuum pumps.

28. A Parylene-coated object, which comprises an object coated with the composition of claim 1.

29. The Parylene-coated object of claim 28, wherein the boron nitride is inter-dispersed the Parylene in the coating.

30. The Parylene-coated object of claim 28, wherein the object is one that benefits from thermal conductivity through the Parylene coating.

31. The Parylene-coated objected of claim 30, wherein the object is generates heat or absorbs heat.

32. The Parylene-coated object of claim 31, wherein the object is selected from the group consisting of electronics equipment, heat packs, refrigeration devices, heaters, and drilling equipment.

33. The Parylene-coated object of claim 28, wherein the object is expected to be subjected to harsh physical impact during its lifetime.

34. The Parylene-coated object of claim 28, wherein the Parylene is selected from the group consisting of Parylene C, Parylene N, Parylene D and Parylene HT®.

35. The Parylene-coated object of claim 34, wherein the polymer is Parylene C.

36. The Parylene-coated object of claim 28, wherein the coating is about 0.0025 mm to about 0.050 mm thick.

37. A polymer-coated object, which comprises an object coated with at least one coat of a polymer and at least one coat of boron nitride.

38. The polymer-coated object of claim 37, wherein the polymer is selected from the group consisting of polynaphtahlene, diamine, polytetrafluoroethylene, polyimides, silicas, titania, aluminum nitride, and lanthanum hexaboride, Parylene C, Parylene N, Parylene D and Parylene HT®.

39. The polymer-coated object of claim 38, wherein the polymer is Parylene C.

40. The polymer coated object of claim 37, wherein the boron nitride coat is closer to the object that the polymer coat.

41. The polymer-coated object of claim 37, wherein the polymer coat is closer to the object that the boron nitride coat.

42. The polymer-coated object of claim 37, where in the coatings of boron nitride and polymer are at least about 0.05 mm thick each.

43. The polymer-coated object of claim 37, wherein the object generates heat or absorbs heat.

44. The polymer-coated object of claim 43, wherein the object is selected from the group consisting of cold packs, frozen liquids and gases and heat pumps.

45. The polymer-coated object of claim 37, wherein the object is expected to be subjected to harsh physical impact during its lifetime.
